(19) United States
(12) Patent Application Publication
(10) Pub. No.: US 2024/0224572 A1
(43) Pub. Date: Jul. 4, 2024

(54) LIGHT-EMITTING ELEMENT, LIGHT-EMITTING DEVICE, AND METHOD OF MANUFACTURING LIGHT-EMITTING ELEMENT

(71) Applicant: Sharp Display Technology Corporation, Kameyama City, Mie (JP)

(72) Inventor: HISAYUKI UTSUMI, Kameyama City, Mie (JP)

(21) Appl. No.: 18/577,167

(22) PCT Filed: Aug. 24, 2021
(86) PCT No.: PCT/JP2021/030930

§ 371 Date: Jan. 5, 2024

(51) Int. Cl. H10K 50/165; C09K 11/54; C09K 11/88; H10K 50/115; H10K 71/12; H10K 85/10; H10K 85/60

(52) U.S. Cl. CPC H10K 50/165; C09K 11/54; C09K 11/88; H10K 50/115; H10K 71/12; H10K 85/111; H10K 85/1135; H10K 85/60

(57) ABSTRACT

A light-emitting element includes: an anode; a cathode; an EML containing QDs therebetween; and an ETL between the cathode and the EML, wherein the ETL contains oxide semiconductor nanoparticles and an oxygen adsorbent.

### TECHNICAL FIELD

The present disclosure relates to light-emitting elements, light-emitting devices, and methods of manufacturing a light-emitting element.

### BACKGROUND ART

Oxide semiconductors have excellent heat resistance and mechanical strength and are safe, inexpensive, and highly adaptable for use in a high temperature environment (see, for example, Patent Literature 1). Therefore, oxide semiconductors exhibit high durability and excellent reliability.

Oxide semiconductors are also capable of transporting carriers. Besides, oxide semiconductors can be prepared in nanoparticle form to readily form a film by coating technology.

For these reasons, oxide semiconductors are prepared, for example, in nanoparticle form for use as an electron transport material in, for example, an electron transport layer in a light-emitting element. The use of oxide semiconductor nanoparticles in the electron transport layer enables obtaining a light-emitting element that exhibits high durability and excellent reliability.

### CITATION LIST

### Patent Literature

Patent Literature 1: Japanese Patent No. 5095517

### SUMMARY

### Technical Problem

However, if the oxide semiconductor is used as an electron transport material in an electron transport layer, the resultant light-emitting elements exhibit appreciably large differences in the characteristics thereof depending on different coating environments.

The inventor has studied and found that the resultant light-emitting element has a significantly reduced external quantum efficiency, thereby suffering from decreases in the evaluation of properties, when an oxide semiconductor-dispersed solution is used in coating in the atmosphere, as compared with when the oxide semiconductor-dispersed solution is used in coating in an inert atmosphere.

Coating with an oxide semiconductor in an inert atmosphere however necessitates investment in equipment for that purpose and also requires adjustment and maintenance of the operating environment, which adds to the production cost.

The present disclosure, in an aspect thereof, has been made in view of these issues and has an object to provide a light-emitting element and a light-emitting device, both including an electron transport layer containing oxide semiconductor nanoparticles, that are manufacturable in the atmosphere and capable of restraining or preventing decreases in the external quantum efficiency even when manufactured in the atmosphere and also to provide a method of manufacturing such a light-emitting element.

### Solution to Problem

To address these issues, the present disclosure, in one aspect thereof, is directed to a light-emitting element including: an anode; a cathode; a quantum-dot light-emitting layer containing quantum dots between the anode and the cathode; and an electron transport layer between the cathode and the quantum-dot light-emitting layer, wherein the electron transport layer contains oxide semiconductor nanoparticles and an oxygen adsorbent.

To address these issues, the present disclosure, in one aspect thereof, is directed to a light-emitting device including the light-emitting element of an aspect thereof of the present disclosure.

To address these issues, the present disclosure, in an aspect thereof, is directed to a method of manufacturing a light-emitting element including: an anode; a cathode; a quantum-dot light-emitting layer containing quantum dots between the anode and the cathode; and an electron transport layer between the cathode and the quantum-dot light-emitting layer, the method including: a step of preparing a colloidal solution containing oxide semiconductor nanoparticles, an oxygen adsorbent, and a solvent; and a step of forming the electron transport layer by forming a coating film of the colloidal solution in the atmosphere and thereafter drying the coating film.

### Advantageous Effects of Disclosure

The present disclosure, in an aspect thereof, can provide a light-emitting element and a light-emitting device, both including an electron transport layer containing oxide semiconductor nanoparticles, that are manufacturable in the atmosphere and capable of restraining or preventing decreases in the external quantum efficiency even when manufactured in the atmosphere and also to provide a method of manufacturing such a light-emitting element.

### BRIEF DESCRIPTION OF DRAWINGS

FIG. 1 is a schematic cross-sectional view of an exemplary structure of a major part of a display area of a display device in accordance with Embodiment 1.

FIG. 2 is a schematic diagram of an exemplary layered structure of a light-emitting element in accordance with Embodiment 1.

FIG. 3 is a schematic view of a red light-emitting element, a green light-emitting element, and a blue light-emitting element positioned next to each other in accordance with Embodiment 1.

FIG. 4 is a flow chart representing exemplary manufacturing steps for a display device in accordance with Embodiment 1.

FIG. 5 is a flow chart representing an example of the step of forming a light-emitting element layer shown in FIG. 4.

FIG. 6 is a schematic cross-sectional view of a part of the step of forming a light-emitting element layer shown in FIG. 4.

### DESCRIPTION OF EMBODIMENTS

### Embodiment 1

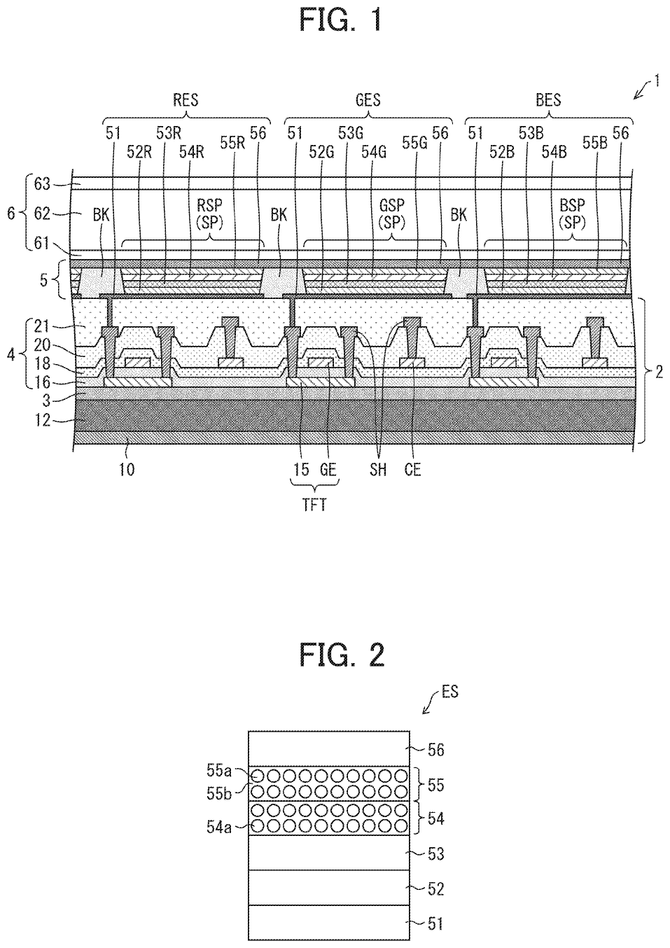

The following will describe an embodiment of the present disclosure with reference to FIGS. 1 to 6. Throughout the description below, the language, “from A to B,” where A and B are both numerical values, refers to “greater than or equal to A and less than or equal to B” unless otherwise mentioned.

The following will describe, as an example of a light-emitting device in accordance with the present embodiment, a display device including quantum-dot light-emitting diodes (hereinafter, “QLEDs”) as light-emitting elements (QLED display device).

### Display Device

FIG. 1 is a schematic cross-sectional view of an exemplary structure of a major part of a display area of a display device 1 in accordance with the present embodiment.

The display device 1 has: a display area in which there is provided a plurality of subpixels SP shown in FIG. 1; and a frame area (not shown) provided around the display area to surround the display area. The frame area is a non-display area. The frame area includes a terminal section (not shown) to which signals for driving the subpixels SP are fed.

Referring to FIG. 1, the display device 1 includes: an array substrate 2; a light-emitting element layer 5 on the array substrate 2; and a sealing layer 6 covering the light-emitting element layer 5.

The array substrate 2 includes, for example: a bottom face film 10; a resin layer 12; a barrier layer 3; and a thin film transistor layer (hereinafter, “TFT layer”) 4 as a drive element layer.

The bottom face film 10 is, for example, a PET (polyethylene terephthalate) film for delivering a highly flexible display device when attached to the bottom face of the resin layer 12 after the support substrate (e.g., mother glass) is lifted off. Note that a solid substrate such as a glass substrate may be used in place of the bottom face film 10 and the resin layer 12. Note also that the resin layer 12 is made of, for example, a polyimide. The portion of the resin layer 12 may be replaced by two resin films (e.g., polyimide films) and an inorganic insulating film interpose between these films.

The barrier layer 3 (undercoat layer) is an inorganic insulating layer for preventing penetration of water, oxygen, and other foreign objects. The barrier layer 3 may be made of, for example, silicon nitride or silicon oxide.

The TFT layer 4 contains TFTs (thin film transistors). The TFT layer 4 includes: a semiconductor film 15; an inorganic insulating film 16 (gate insulating film) overlying the semiconductor film 15; gate electrodes GE and gate lines GH overlying the inorganic insulating film 16; an inorganic insulating film 18 overlying the gate electrodes GE and the gate lines GH; capacitor electrodes CE overlying the inorganic insulating film 18; an inorganic insulating film 20 overlying the capacitor electrodes CE; wiring including source lines SH overlying the inorganic insulating film 20; and a planarization film 21 (interlayer insulating film) overlying the source lines SH. The TFT layer 4 includes TFTs formed therein as drive elements so as to include the semiconductor film 15 and the gate electrodes GE.

The semiconductor film 15 is made of, for example, a low-temperature polysilicon (LTPS) or an oxide semiconductor. Note that FIG. 1 shows TFTs having a top-gate structure with the semiconductor film 15 as the channel. Alternatively, the TFTs may have a bottom-gate structure.

The barrier layer 3 and the inorganic insulating films 16, 18, and 20 may each include, for example, a silicon oxide (SiOx) film, a silicon nitride (SiNx) film, or a stack of these films. The films can be formed by, for example, CVD (chemical vapor deposition). The planarization film 21 may be made of, for example, a polyimide, an acrylic resin, or a like organic material that can be provided by coating technology.

The gate electrodes GE, the capacitor electrodes CE, the source lines SH, and other like wiring include, for example, a monolayer metal film containing at least one of Al (aluminum), W (tungsten), Mo (molybdenum), Ta (tantalum), Cr (chromium), Ti (titanium), and Cu (copper) or a stack of any of these films.

The sealing layer 6 prevents permeation of the light-emitting element layer 5 by water, oxygen, and other foreign objects. Note that the light-emitting element layer 5 will be detailed later in the description.

Referring to FIG. 1, the sealing layer 6 includes: an inorganic sealing film 61; an organic buffer film 62 overlying the inorganic sealing film 61; and an inorganic sealing film 63 overlying the organic buffer film 62.

The inorganic sealing film 61 and the inorganic sealing film 63 are light-transmitting inorganic insulating films and includes, for example, a silicon oxide (SiOx) film, a silicon nitride (SiNx) film, a silicon oxynitride film (SiNO), or a stack of any of these films. The films can be formed by, for example, CVD (chemical vapor deposition).

The organic buffer film 62 is a light-transmitting organic film that provides a planarization effect and may be made of an acrylic resin or a like organic material that can be provided by coating technology. The organic buffer film 62 can be formed by, for example, inkjet coating and may include a bank (not shown) provided in the frame area for stopping liquid drops.

In addition, on the sealing layer 6, there may be provided a functional film that is selected in a suitable manner depending on the application. Examples of this functional film include a functional film capable of at least one of the optical compensation function, the touch sensor function, and the protection function. Note that when the display device 1 is a solid display device (i.e., a non-flexible display device), the functional film may be replaced by a touch panel, a polarizer, or a glass substrate such as cover glass.

Throughout the present embodiment, the direction from the array substrate 2 toward the sealing layer 6 is referred to as “upward,” and the opposite direction is referred to as “downward.” In addition, throughout the present embodiment, expressions like “component A underlies/is below component B” indicate that component A is formed in an earlier process or step than component B, and expressions like “component A overlies/is on or above component B” indicate that component A is formed in a later process or step than component B.

The display device 1 is a QLED display device. The light-emitting element layer 5 is a QLED layer including a plurality of QLEDs as light-emitting elements ES. Each light-emitting element ES corresponds to a different one of the subpixels SP, so that each subpixel SP includes one light-emitting element ES.

FIG. 2 is a schematic diagram of an exemplary layered structure of the light-emitting element ES in accordance with the present embodiment.

Referring to FIG. 2, the light-emitting element ES includes at least: an anode 51; a cathode 56; a light-emitting layer (hereinafter, “EML”) 54 between the anode 51 and the cathode 56; and an electron transport layer (hereinafter, “ETL”) 55 between the cathode 56 and the EML 54.

The layers between the anode 51 and the cathode 56 are collectively referred to as the functional layers in the present embodiment. FIG. 2 shows, as an example, the functional layers including: a hole injection layer (hereinafter, “HIL”) 52; a hole transport layer (hereinafter, “HTL”) 53; the EML 54; and the ETL 55, in this order when viewed from the anode 51 side. Note that structures are also possible where either one or both of the HIL 52 and the HTL 53 may be missing.

The following will describe an example where the underlying electrode, which is an electrode on the underlying side, is the anode 51 and the overlying electrode, which is an electrode on the overlying side, is the cathode 56, as shown in FIG. 2. The light-emitting element ES shown in FIG. 2 has a structure in which the anode 51, the HIL 52, the HTL 53, the EML 54, the ETL 55, and the cathode 56 are stacked in this order when viewed from the underlying side.

Referring to FIG. 1, the display device 1 includes as the subpixels, for example, a red light-emitting subpixel RSP (red subpixel), a green light-emitting subpixel GSP (green subpixel), and a blue light-emitting subpixel BSP (blue subpixel).

The subpixel RSP includes a light-emitting element RES that emits red light (red light-emitting element or red QLED) as one of the light-emitting elements ES. The subpixel GSP includes a light-emitting element GES that emits green light (green light-emitting element or green QLED) as one of the light-emitting elements ES. The subpixel BSP includes a light-emitting element BES that emits blue light (blue light-emitting element or blue QLED) as one of the light-emitting elements ES.

Here, “red light” refers to light that has a peak emission wavelength in a wavelength range from 600 nm, exclusive, to 780 nm, inclusive. “Green light” refers to light that has a peak emission wavelength in a wavelength range from 500 nm, exclusive, to 600 nm, inclusive. “Blue light” refers to light that has a peak emission wavelength in a wavelength range from 400 nm to 500 nm, both inclusive.

Note that throughout the present embodiment, the light-emitting elements RES, the light-emitting elements GES, and the light-emitting elements BES are collectively referred to as the “light-emitting elements ES” when there is no particular need to distinguish between the light-emitting elements RES, the light-emitting elements GES, and the light-emitting elements BES. In addition, throughout the present embodiment, the subpixels RSP, the subpixels GSP, and the subpixels BSP are collectively referred to as the subpixels SP when there is no particular need to distinguish between the subpixels RSP, the subpixels GSP, and the subpixels BSP. In addition, the layers in the light-emitting elements ES are similarly referred to when there is no particular need to distinguish between the light-emitting elements RES, the light-emitting elements GES, and the light-emitting elements BES.

Referring to FIG. 1, the anode 51, the HIL 52, the HTL 53, the EML 54, and the ETL 55 in each subpixel SP are separated in an insular manner from the other subpixels SP by a bank BK that covers the edge of the anode 51, which is the underlying electrode. Meanwhile, the cathode 56, which is the overlying electrode, is not separated by the bank BK, but provided as a common layer that is common to all the subpixels SP. Therefore, in the present embodiment, the anode 51 is an insularly patterned anode (patterned anode). The anode 51 in each subpixel SP is electrically connected to an associated one of the plurality of TFTs in the TFT layer 4. The cathode 56 is a cathode that is common to all the subpixels SP (common cathode).

The light-emitting element RES shown in FIG. 1 includes: an HIL 52R as the HILL 52; an HTL 53R as the HTL 53; an EML 54R as the EML 54; and an ETL 55R as the ETL 55. The light-emitting element GES shown in FIG. 1 includes: an HIL 52G as the HIL 52; an HTL 53G as the HTL 53; an EML 54G as the EML 54; and an ETL 55G as the ETL 55. The light-emitting element BES shown in FIG. 1 includes: an HIL 52B as the HIL 52; an HTL 53B as the HTL 53; an EML 54B as the EML 54; and an ETL 55B as the ETL 55.

Therefore, the light-emitting element RES shown in FIG. 1 has a structure in which the anode 51, the HIL 52R, the HTL 53R, the EML 54R, the ETL 55R, and the cathode 56 are stacked in this order when viewed from the array substrate 2 side. The light-emitting element GES shown in FIG. 1 has a structure in which the anode 51, the HIL 52G, the HTL 53G, the EML 54G, the ETL 55G, and the cathode 56 are stacked in this order when viewed from the array substrate 2 side. The light-emitting element BES shown in FIG. 1 has a structure in which the anode 51, the HIL 52B, the HTL 53B, the EML 54B, the ETL 55B, and the cathode 56 are stacked in this order when viewed from the array substrate 2 side.

As described above, the bank BK functions as an edge cover covering the edge of the anode 51 and also as a subpixel separation film (light-emitting element separation film).

The bank BK is formed by, for example, coating with an organic material such as a polyimide or an acrylic resin and thereafter patterning by photolithography.

The anode 51 and the cathode 56 are configured such that a voltage is applied across the anode 51 and the cathode 56 when connected to a power supply (e.g., DC power supply) (not shown). One of the anode 51 and the cathode 56 that is on the underlying side is electrically connected to one of the TFTs in the TFT layer 4.

The anode 51 supplies holes to the EML 54 when placed under an applied voltage. The anode 51 contains a conductive material and is electrically connected to the HIL 52.

The cathode 56 supplies electrons to the EML 54 when placed under an applied voltage. The cathode 56 contains a conductive material and is electrically connected to the ETL 55.

One of the anode 51 and the cathode 56 that is disposed on the light-extracting side of the light-emitting element ES needs to be light-transmitting. Each of the anode 51 and the cathode 56 may be a monolayer or a stack of layers.

When the light-emitting element ES is a top-emission type of display element from the top face side (in other words, the overlying electrode side) of which light is extracted, the overlying electrode is a light-transmitting electrode that transmits light, and the underlying electrode is a so-called reflective electrode that, for example, reflects light.

On the other hand, when the light-emitting element ES is a bottom-emission type of display element from the bottom face side (in other words, the underlying electrode side) of which light is extracted, the underlying electrode is a light-transmitting electrode, and the overlying electrode is a reflective electrode.

The light-transmitting electrode is made of, for example, a light-transmitting material such as a thin film of ITO (indium tin oxide), IZO (indium zinc oxide), Ag NW (silver nanowire), or a Mg—Ag (magnesium-silver) alloy or a thin film of Ag (silver).

The reflective electrode may be made of, for example, a light-reflective material such as a metal such as Ag or Al (aluminum) or an alloy containing any of these metals and may be formed by stacking a light-transmitting material and a light-reflective material. Therefore, the reflective electrode may have a layered structure of, for example, ITO/Ag alloy/ITO, ITO/Ag/ITO, or Al/IZO.

The EML 54 is a quantum-dot light-emitting layer and contains quantum dots (hereinafter, “QDs”) 54a as a light-emitting material. Note that in FIG. 2, for convenience of illustration, the QDs 54a are shown enlarged, and not all the QDs 54a are shown.

Holes and electrons recombine in the EML 54 under the drive current flowing between the anode 51 and the cathode 56, which generates excitons that emit light when transitioning from the conduction band energy level to the valence band energy level of the QDs 54a.

The QDs 54a are inorganic nanoparticles composed of approximately a few thousands of atoms to a few tens of thousands of atoms and having particle diameters of approximately from a few nanometers to a few tens of nanometers. The QDs 54a are alternatively called fluorescent nanoparticles or QD fluorescent material particles because the QDs 54a fluorescence and have nanometer dimensions. Additionally, the QDs 54a are alternatively called semiconductor nanoparticles because the QDs 54a are made of a semiconductor material. Additionally, the QDs 54a are alternatively called nanocrystals because the QDs 54a have a specific crystalline structure.

These QDs 54a may contain, for example, a semiconductor material containing at least one element selected from the group consisting of Cd (cadmium), S (sulfur), Te (tellurium), Se (selenium), Zn (zinc), In (indium), N (nitrogen), P (phosphorus), As (arsenic), Sb (antimony), Al (aluminum), Ga (gallium), Pb (lead), Si (silicon), Ge (germanium), and Mg (magnesium).

In addition, the QDs 54a may have a two-component core structure, a three-component core structure, a four-component core structure, a core-shell structure, or a core-multishell structure. In addition, the QDs 54a may contain doped nanoparticles and may have a composition gradient structure.

The QDs 54a are able to have various emission wavelengths, depending on the particle diameters, composition, and other conditions. In other words, the above-described red, green, and blue light can be realized by adjusting the particle diameters and composition of the QDs 54a in a suitable manner. Examples of such QDs 54a include CdSe (cadmium selenide), InP (indium phosphide), and ZnSe (zinc selenide).

The display device 1 includes the QDs 54a that have a different emission wavelength peak for each color as a light-emitting material in the subpixels SP.

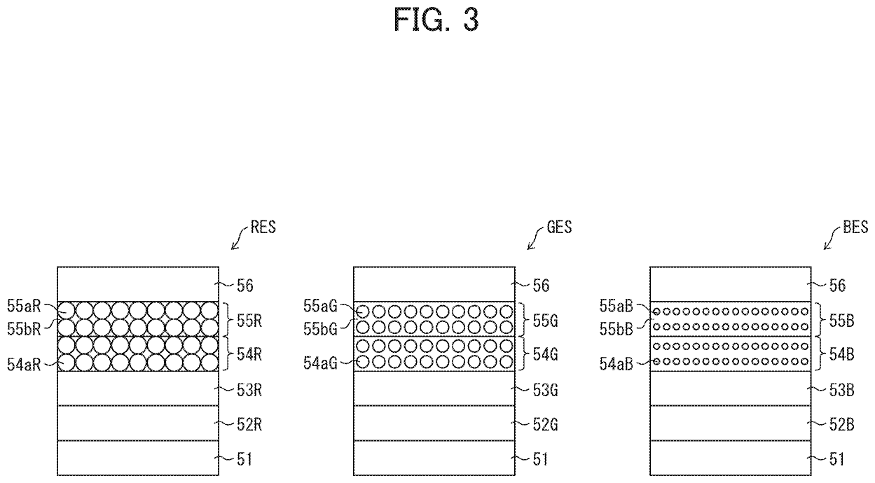

FIG. 3 is a schematic view of one of the light-emitting elements RES, one of the light-emitting elements GES, and one of the light-emitting elements BES positioned next to each other.

Referring to FIG. 3, the EML 54R in the subpixel RSP contains red QDs 54aR as the QDs 54a, the EML 54G in the subpixel GSP contains green QDs 54aG as the QDs 54a, and the EML 54B in the subpixel BSP contains blue QDs 54aB as the QDs 54a. Note that in FIG. 3, for convenience of illustration, the QDs 54aR, the QDs 54aG, and the QDs 54aB are shown enlarged, and not all the QDs 54aR, the QDs 54aG, and the QDs 54aB are shown.

Throughout the present embodiment, the QDs 54aR, the QDs 54aG, and the QDs 54aB are collectively and simply referred to as the QDs 54a as described above when there is no particular need to distinguish between the QDs 54aR, the QDs 54aG, and the QDs 54aB. As described here, the EML 54 contains a plurality of types of QDs 54a, and each subpixel SP contains a single type of QDs 54a.

The HIL 52 and the HTL 53 are provided in this order between the anode 51 and the EML 54 when viewed from the anode 51 side as described above.

The HIL 52 has hole transportability and facilitates hole injection from the anode 51 to the HTL 53. The HTL 53 has hole transportability and transports the holes injected from the HIL 52 to the EML 54. The HIL 52 and the HTL 53 each contain a hole transport material. These hole transport materials may be publicly known hole transport materials.

The hole transport material used in the HIL 52 is not limited in any particular manner and may be, for example, PEDOT:PSS. Note that PEDOT:PSS is a composite of PEDOT (poly(3,4-ethylenedioxythiophene)) and PSS (poly(4-styrene sulfonate)). Any one of these hole transport materials may be used alone; alternatively, two or more of the materials may be used in the form of mixture where appropriate. In addition, the HTL 53R, the HTL 53G, and the HTL 53B may be made either of the same material or of materials with different hole mobilities.

The hole transport material used for the HTL 53 is not limited in any particular manner and may be, for example, TFB (poly[(9,9-dioctylfluorenyl-2,7-diyl)-co-(4,4′-(N-4-sec-butylphenyl))diphenylamine)), p-TPD (poly[N,N′-bis(4-butylphenyl)-N,N′-bis(phenyl)-benzidine]), or PVK (polyvinyl carbazole). Any one of these hole transport materials may also used alone; alternatively, two or more of the materials may be used in the form of mixture where appropriate. In addition, the HTL 53R, the HTL 53G, and the HTL 53B may be made either of the same material or of materials with different hole mobilities.

Referring to FIG. 2, the ETL 55 is disposed between the cathode 56 and the EML 54 as described earlier. The ETL 55 has electron transportability and transports electrons from the cathode 56 to the EML 54. Note that the ETL 55 may have a function of disturbing the transport of holes.

The ETL 55 contains nanoparticles of an oxide semiconductor (hereinafter, “oxide semiconductor nanoparticles”) 55a as an electron transport material. Note that in FIG. 2, for convenience of illustration, the oxide semiconductor nanoparticles 55a are shown enlarged, and not all the oxide semiconductor nanoparticles 55a are shown.

The oxide semiconductor nanoparticles 55a are not limited in any particular manner so long as the oxide semiconductor nanoparticles 55a are nanosized particles of an oxide semiconductor that have electron transportability. The oxide semiconductor nanoparticles 55a may be, for example, a known oxide semiconductor nanoparticles known as an electron transport material. The oxide semiconductor nanoparticles 55a may be, for example, nanoparticles of a n-type metal oxide known as a n-type oxide semiconductor. Examples of such an oxide semiconductor (metal oxide) include zinc- (Zn-)containing oxide semiconductors such as ZnO (zinc oxide) and ZnMgO (zinc magnesium oxide). Among oxide semiconductors, Zn-containing oxide semiconductors such as ZnO and ZnMgO have a large band gap and are generally known as an electron transport material. Therefore, the oxide semiconductor is preferably a Zn-containing oxide semiconductor.

ZnO, among these oxide semiconductors, has a particularly large band gap, thereby facilitating electron injection to a light-emitting material and hence enabling improving the luminous efficiency of the EML 54. In addition, ZnO has particularly high durability and particularly excellent reliability, and can be prepared in such nanoparticle form that a film can be easily made by coating technology. Therefore, ZnO is particularly suitable as an electron transport material. By using ZnO as the oxide semiconductor, the resultant light-emitting element ES has particularly high durability, particularly excellent reliability, and high luminous efficiency.

It should be noted however that the present embodiment is not limited to these examples. Examples of n-type metal oxides known as n-type oxide semiconductors include, apart from ZnO and ZnMgO, TiO₂ (titanium oxide), In₂O₃ (indium oxide), SnO₂ (tin oxide), CeO₂ (cerium oxide), tantalum oxide (Ta₂O₃), and strontium oxide titanium (SrTiO₃). Any one of these oxide semiconductors, including ZnO and ZnMgO, may be used alone; alternatively, two or more of the materials may be used in the form of mixture where appropriate.

As described above, oxide semiconductors have excellent heat resistance and mechanical strength and are safe, inexpensive, and highly adaptable for use in a high temperature environment. Therefore, the oxide semiconductor nanoparticles 55a have high durability and excellent reliability. In addition, the oxide semiconductor nanoparticles 55a can be made into a film by coating, which facilitates film formation. Therefore, by using the oxide semiconductor nanoparticles 55a as the electron transport material, the resultant light-emitting element ES has high durability and excellent reliability.

However, as described above, the resultant light-emitting element ES has a significantly reduced external quantum efficiency, thereby suffering from decreases in the evaluation of properties, when an oxide semiconductor-dispersed solution is used in coating in the atmosphere, as compared with when the oxide semiconductor-dispersed solution is used in coating in an inert atmosphere.

In view of this situation, the ETL 55 in accordance with the present embodiment contains an oxygen adsorbent 55b as well as the oxide semiconductor nanoparticles 55a. The oxygen adsorbent 55b is an oxygen adsorbent (antioxidant) that prevents the oxidation of the surfaces of the oxide semiconductor nanoparticles 55a by adsorbing oxygen. Note that any single type of the oxygen adsorbent 55b may be used alone; alternatively, two or more types of the oxygen adsorbent 55b may be used in the form of mixture where appropriate.

If an electron transport material containing the oxide semiconductor nanoparticles 55a is used in coating in the atmosphere to form the ETL 55, oxygen in the air is adsorbed onto the surfaces of the oxide semiconductor nanoparticles 55a, thereby prompting oxidation of the surfaces of the oxide semiconductor nanoparticles 55a. This phenomenon moves the oxidation-reduction potential to the positive side. The oxidation-reduction potential is simply linear to the conduction band energy level. As the oxidation-reduction potential moves to the positive side due to oxidation, the conduction band minimum is deepened, the band gap is narrowed down, and the height of the electron injection barrier is increased. In addition, the oxygen adsorbed onto the surfaces of the oxide semiconductor nanoparticles 55a has such a large electron affinity as to attract electrons from the conduction band of the oxide semiconductor nanoparticles 55a, thereby becoming negative ions for chemical adsorption. An electron-depleted layer depleted with electrons forms on the surfaces of the oxide semiconductor nanoparticles 55a to neutralize this negative electric charge. The electron-depleted layer presents a barrier to the flow of electrons. Therefore, when oxygen molecules in the air is adsorbed onto the surfaces of the oxide semiconductor nanoparticles 55a, the external quantum efficiency of the light-emitting element ES decreases, which leads to decreases in the evaluation of properties.

For this reason, the known light-emitting element needs to be manufactured in an inert atmosphere. On the other hand, according to the present embodiment, the ETL 55 containing the oxygen adsorbent 55b as described above allows for the oxygen adsorbent 55b, not the oxide semiconductor nanoparticles 55a, to adsorb oxygen in the atmosphere, thereby enabling restraining or preventing the adsorption of oxygen onto the surfaces of the oxide semiconductor nanoparticles 55a. This mechanism enables restraining or preventing the movement of the oxidation-reduction potential of the oxide semiconductor nanoparticles 55a to the positive side. Therefore, even if the light-emitting element ES is manufactured in the atmosphere, the present embodiment enables restraining or preventing decreases in the external quantum efficiency of the light-emitting element ES caused by oxidation of the oxide semiconductor nanoparticles 55a, hence enabling manufacture in the atmosphere of the light-emitting element ES including the ETL 55 containing the oxide semiconductor nanoparticles 55a.

The ETL 55 is formed by coating with a colloidal solution (dispersed solution, electron transport layer material colloidal solution) prepared by dispersing the oxide semiconductor nanoparticles 55a in a solvent in colloidal form. Therefore, an oxygen adsorbent that dissolves in the colloidal solution is used as the oxygen adsorbent 55b. Note that throughout the present disclosure, the term, “dissolution,” refers not only to the decomposition of the oxygen adsorbent 55b to ions, but also to the dispersion of the oxygen adsorbent 55b in colloidal form.

The oxide semiconductor generally disperses in polar organic solvents. Meanwhile, QDs are in many cases dispersed in a non-polar organic solvent for use in coating. Therefore, to dissolve the oxygen adsorbent 55b in the colloidal solution, an oxygen adsorbent that dissolves in a polar organic solvent is preferably used as the oxygen adsorbent 55b.

The dissolution of the oxygen adsorbent 55b in a polar organic solvent enables use of a polar organic solvent to form the ETL 55. In this arrangement, when the ETL 55 is formed on the EML 54, the formation of the ETL 55 inhibits the EML 54 from dissolving, thereby preventing the EML 54 from being damaged. In addition, when the EML 54 is formed on the ETL 55 as will be described later, the formation of the EML 54 inhibits the ETL 55 from dissolving, thereby preventing the ETL 55 from being damaged.

The polar organic solvent is an organic solvent that has a Hildebrand solubility parameter (δ, SP value level) of suitably 10.0 or higher, more suitably from 10.0 to 14.8, both inclusive. The Hildebrand solubility parameter is defined by the square root of cohesive energy density. The polar organic solvent is, for example, ethanol (12.7) or 1-butanol (11.4). Note that the numeric value in the parentheses following the name of an organic solvent gives the SP value of the organic solvent.

In addition, the non-polar organic solvent is suitably an organic solvent with an SP value of from 6.5 to 9.4, both inclusive. The polar organic solvent is, for example, octane (7.5). Note that the numeric value in the parentheses following the name of an organic solvent gives the SP value of the organic solvent.

The oxygen adsorbent 55b is suitably, for example, an aromatic oxygen adsorbent. Aromatic oxygen adsorbents are highly soluble (dispersible) in polar organic solvents. In addition, the aromatic oxygen adsorbent can also function as a dispersant for dispersing the oxide semiconductor nanoparticles 55a when the aromatic oxygen adsorbent is, for example, coordinated to the oxide semiconductor nanoparticles 55a as a surface-modification agent for modifying the surfaces of the oxide semiconductor nanoparticles 55a. Therefore, the colloidal solution can be prepared without having to separately use a dispersant. In addition, the aromatic oxygen adsorbent does not adversely affect the electrical properties, such as the conductivity, of the ETL 55, thereby not adversely affecting EL light emission. Besides, by using an aromatic oxygen adsorbent as the oxygen adsorbent 55b, the resultant light-emitting element ES is excellent in restraining and preventing decreases in the external quantum efficiency caused by oxidation of the oxide semiconductor nanoparticles 55a.

Among these aromatic oxygen adsorbents, the oxygen adsorbent 55b is suitably, for example, a phenolic oxygen adsorbent. Phenolic oxygen adsorbents exhibit excellent thermostability. In addition, by using the phenolic oxygen adsorbent, among the aromatic oxygen adsorbents, the resultant light-emitting element ES is excellent in restraining and preventing decreases in the external quantum efficiency caused by oxidation of the oxide semiconductor nanoparticles 55a.

Examples of the phenolic oxygen adsorbent include, dibutylhydroxytoluene (BHT, alternative name: 2,6-di-tert-butyl-p-cresol), 2,6-di-tert-butyl-4-methoxyphenol (BMP), 3-tert-butyl-4-hydroxyanisole (3-BHA), tert-butylhydroquinone (TBHQ), and 2,4,5-trihydroxybutylphenone (THBP). As described above, any one of these oxygen adsorbents 55b may be used alone; alternatively, two or more types of the oxygen adsorbent 55b may be used in the form of mixture where appropriate.

Among these phenolic oxygen adsorbents, at least one species selected from the group consisting of BHT, BMP, and 3-BHA can be suitably used. By using one of these phenolic oxygen adsorbents among various phenolic oxygen adsorbents, the resultant light-emitting element ES is more excellent in restraining and preventing decreases in the external quantum efficiency caused by oxidation of the oxide semiconductor nanoparticles 55a.

In addition, among these phenolic oxygen adsorbents, BHT is particularly preferred for its high capability of restraining and preventing decreases in the external quantum efficiency of the resultant light-emitting element ES. Therefore, the oxygen adsorbent 55b more preferably contains BHT.

It should be noted however that the present embodiment is not limited to these examples. The aromatic oxygen adsorbent is not limited to a phenolic oxygen adsorbent and may be, for example, benzotriazole or a like non-phenolic aromatic oxygen adsorbent with a benzene ring. The aromatic oxygen adsorbent is preferably such an aromatic oxygen adsorbent with a benzene ring.

In addition, examples of the oxygen adsorbent 55b, other than aromatic oxygen adsorbents, include ascorbic acid, tocopherol, sodium sulfite, and potassium sulfite. The oxygen adsorbent 55b may be any one of these oxygen adsorbents. It should be noted however that the oxygen adsorbent 55b is preferably an aromatic oxygen adsorbent in view of the solubility (dispersibility) in a colloidal solution containing the oxide semiconductor nanoparticles 55a and in view of the electrical properties of the ETL 55 containing the oxygen adsorbent 55b.

The ETL 55 contains the oxygen adsorbent 55b in an amount of preferably from 0.2 parts by weight to 1.2 parts by weight, both inclusive, more preferably from 0.2 parts by weight to 1 part by weight, both inclusive, and even more preferably from 0.2 parts by weight to 0.6 parts by weight, both inclusive, per 1 part by weight of the oxide semiconductor nanoparticles 55a. By choosing the composition ratio of the oxide semiconductor nanoparticles 55a and the oxygen adsorbent 55b in the ETL 55 from one of these ranges, the resultant light-emitting element ES is excellent in restraining and preventing decreases in the external quantum efficiency caused by oxidation of the oxide semiconductor nanoparticles 55a.

Note that the ETL 55R, the ETL 55G, and the ETL 55B may be made of either the same material or different materials.

Referring to FIG. 3, the EML 54R in the subpixel RSP contains oxide semiconductor nanoparticles 55aR as the oxide semiconductor nanoparticles 55a, the EML 54G in the subpixel GSP contains oxide semiconductor nanoparticles 55aG as the oxide semiconductor nanoparticles 55a, and the EML 54B in the subpixel BSP contains oxide semiconductor nanoparticles 55aB as the oxide semiconductor nanoparticles 55a.

In addition, referring to FIG. 3, the EML 54R in the subpixel RSP contains an oxygen adsorbent 55bR as the oxygen adsorbent 55b, the EML 54G in the subpixel GSP contains an oxygen adsorbent 55bG as the oxygen adsorbent 55b, and the EML 54B in the subpixel BSP contains an oxygen adsorbent 55bB as the oxygen adsorbent 55b.

Note that throughout the present embodiment, the oxide semiconductor nanoparticles 55aR, the oxide semiconductor nanoparticles 55aG, and the oxide semiconductor nanoparticles 55aB are collectively and simply referred to as the “oxide semiconductor nanoparticles 55a” as described above, when there is no particular need to distinguish between these oxide semiconductor nanoparticles 55aR, oxide semiconductor nanoparticles 55aG, and oxide semiconductor nanoparticles 55aB. Likewise, the oxygen adsorbent 55bR, the oxygen adsorbent 55bG, and the oxygen adsorbent 55bB are collectively and simply referred to as the “oxygen adsorbent 55b” as described above, when there is no particular need to distinguish between these oxygen adsorbent 55bR, oxygen adsorbent 55bG, and oxygen adsorbent 55bB.

The oxide semiconductor nanoparticles 55aR, the oxide semiconductor nanoparticles 55aG, and the oxide semiconductor nanoparticles 55aB may be made of either the same material or different materials. In other words, the oxide semiconductor nanoparticles 55aR, the oxide semiconductor nanoparticles 55aG, and the oxide semiconductor nanoparticles 55aB may contain either the same components or different components. Likewise, the oxygen adsorbent 55bR, the oxygen adsorbent 55bG, and the oxygen adsorbent 55bB may contain either the same components or different components.

In addition, apart from the components, the oxide semiconductor nanoparticles 55aR, the oxide semiconductor nanoparticles 55aG, and the oxide semiconductor nanoparticles 55aB may have either the same particle diameter (e.g., median diameter) or different particle diameters.

For instance, the volume median diameter (D50) of each oxide semiconductor nanoparticle 55a is preferably from 1.5 nm to 8 nm, both inclusive.

When the oxide semiconductor nanoparticles 55a decrease in particle diameter (volume median diameter), the oxide semiconductor nanoparticles 55a are more likely to condense and exhibit low dispersibility in a solvent, and on the other hand, more likely to have a large band gap and facilitate electron injection to the light-emitting material. Therefore, the oxide semiconductor nanoparticles 55a preferably have a particle diameter (volume median diameter) that falls in the foregoing range. Note that here, the volume median diameter (D50) represents the particle diameter when the cumulative percentage is equal to 50% in a cumulative particle-size distribution in terms of volume (cumulative average diameter).

In the present embodiment, the volume median diameter (D50) was measured with a nanoparticle diameter measuring instrument (model number: “Nanotrac Wave II-UT151”) manufactured by MicrotracBEL Corp, using a 20-mg/mL ethanol solution of the oxide semiconductor nanoparticles 55a as measurement samples. Analysis was done by frequency analysis by dynamic light scattering (DLS). The particle diameter was measured by heterodyne technique.

As described here, all the oxide semiconductor nanoparticles 55a contained in each ETL 55 are preferably so prepared as to have a volume median diameter (D50) that falls in the foregoing range.

It should be noted however that the oxide semiconductor nanoparticles 55a more preferably have a volume median diameter (D50) that corresponds to the color of the light emitted by the light-emitting material (emission wavelength).

For instance, in the ETL 55R in the light-emitting element RES, the oxide semiconductor nanoparticles 55aR preferably have a volume median diameter (D50) of from 5 nm to 8 nm, both inclusive. In addition, in the ETL 55G in the light-emitting element GES, the oxide semiconductor nanoparticles 55aG preferably have a volume median diameter (D50) of from 3 nm to 5 nm, both inclusive. In the ETL 55B in the light-emitting element BES, the oxide semiconductor nanoparticles 55aB preferably have a volume median diameter (D50) of from 1.5 nm to 3 nm, both inclusive.

As described here, for the oxide semiconductor nanoparticles 55a, there is a particle diameter that is suitable for the color of light emitted by the light-emitting material in the EML 54.

Note that the thickness of each layer in the light-emitting element ES is not limited in any particular manner and may be specified in the same manner as in known examples. The layers in the light-emitting element RES, the light-emitting element GES, and the light-emitting element BES may have either the same thickness or different thicknesses. Preferably, the ETL 55 has a thickness of, for example, from 30 to 100 nm. This particular arrangement inhibits occurrence of pinholes and changes in the chromaticity (hue) of the color of emitted light, thereby enabling achieving even higher external quantum efficiency. In addition, by specifying the composition ratio of the oxide semiconductor nanoparticles 55a and the oxygen adsorbent 55b in the ETL 55 to fall in the foregoing range, the present embodiment not only enables restraining and preventing oxidation of the oxide semiconductor nanoparticles 55a, but also inhibits the efficiency of electron transport by the oxide semiconductor nanoparticles 55a from falling even when the thickness of the ETL 55 is specified in the same manner as in known examples. Therefore, even when the ETL 55 contains the oxygen adsorbent 55b, the ETL 55 can be prevented from having an excessively large thickness.

### Method of Manufacturing Display Device 1

A description is given next of a method of manufacturing the display device 1.

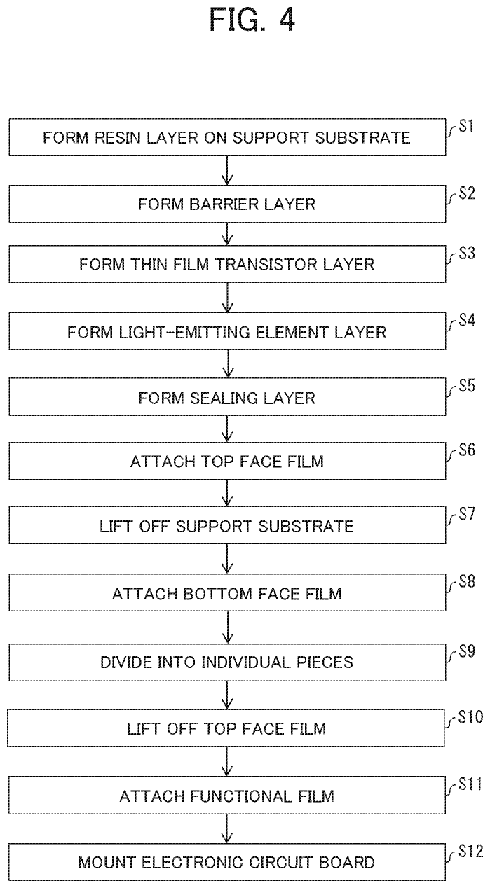

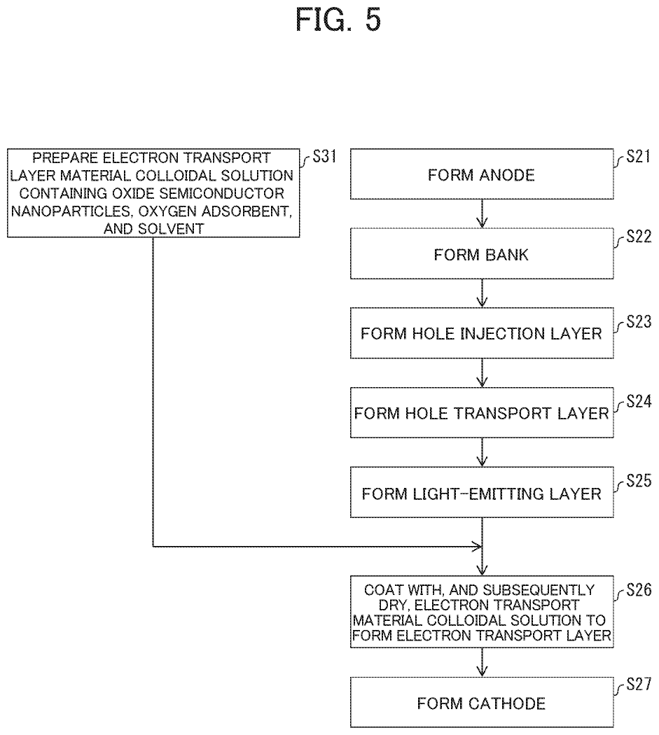

FIG. 4 is a flow chart representing exemplary manufacturing steps for the display device 1 in accordance with the present embodiment.

The following will describe an example where a flexible display device is manufactured as the display device 1.

To manufacture a flexible display device as the display device 1, as shown in FIG. 4, first of all, the resin layer 12 is formed on a transparent support substrate (e.g., mother glass; not shown) (step S1). Next, the barrier layer 3 is formed (step S2). Next, the TFT layer 4 is formed (step S3). Next, the light-emitting element layer 5 is formed (step S4). Next, the sealing layer 6 is formed (step S5). Next, a protective top face film (not shown) is temporarily attached onto the sealing layer 6 (step S6). Next, the support substrate is detached from the resin layer 12 by, for example, laser irradiation (step S7). Next, the bottom face film 10 is attached to the bottom face of the resin layer 12 (step S8). Next, the stack of the bottom face film 10, the resin layer 12, the barrier layer 3, the TFT layer 4, the light-emitting element layer 5, the sealing layer 6, and the top face film is divided to obtain a plurality of individual pieces (step S9). Next, after the top face film is detached from the obtained individual pieces (step S10), a functional film is attached (step S11). Next, an electronic circuit board (e.g., IC chip or FPC; not shown) is mounted on a part (terminal portion) that is outside of the display area (in the frame area) where the plurality of subpixels SP are provided (step S12).

Note that steps S1 to S12 are performed by display device manufacturing equipment (including a film-forming machine that performs steps S1 to S5).

In addition, the top face film is, as described above, attached onto the sealing layer 6 and serves as a support member when the support substrate is detached. The top face film may be, for example, a PET (polyethylene terephthalate) film.

Note that the preceding description has discussed a method of manufacturing a flexible display device 1. However, when a non-flexible display device 1 is manufactured, it is generally unnecessary to, for example, form the resin layer 12 and change base members. Therefore, to manufacture a non-flexible display device 1, for example, the stacking steps of S2 to S5 are performed on a glass substrate, and thereafter the process proceeds to step S9.

FIG. 5 is a flow chart representing exemplary steps of forming the light-emitting element layer 5 indicated as step S4 in FIG. 4. Note that FIG. 5 describes a step of forming the light-emitting element layer 5 shown in FIG. 1 as an example. The step of forming the light-emitting element layer 5 may be alternatively called the step of manufacturing the light-emitting element ES.

Referring to FIG. 5, in the step of forming the light-emitting element layer 5, first of all, the anode 51 is formed on the TFT layer 4 (in other words, on the array substrate 2) (step S21). Next, the bank BK is formed so as to cover the edge of the anode 51 (step S22). Next, the HIL 52 (hole injection layer) is formed (step S23). Next, the HTL 53 (hole transport layer) is formed (step S24). Next, the EMLs 54 (light-emitting layer) are formed (step S25). Next, the ETL 55 (electron transport layer) is formed (step S26). Next, the cathode 56 is formed (step S27).

Note that the step of forming the light-emitting element layer 5 further involves separately an electron transport layer material colloidal solution preparation step of preparing an electron transport layer material colloidal solution used to form an ETL 56 before step S26 (step S31).

In step S21 and step S27, the anode 51 and the cathode 56 can be formed by, for example, physical vapor deposition (PVD) such as sputtering or vacuum vapor deposition, spin-coating, or inkjet printing.

Note that in step S21, the anode 51 is formed by patterning for each subpixel SP. In contrast, in step S27, the cathode 56 is formed commonly across all the subpixels SP.

In step S22, the bank BK can be formed in a desirable shape by patterning, for example, by photolithography, a layer of an insulating material deposited by, for example, PVD such as sputtering or vacuum vapor deposition, spin-coating, or inkjet printing.

The formation of the HIL 52 in step S23 and the formation of the HTL 53 in step S24 are done by, for example, PVD such as sputtering or vacuum vapor deposition, spin-coating, or inkjet printing.

In step S25, the EMLs 54 may be formed by coating with a colloidal QD solution containing QDs and a solvent and thereafter drying the colloidal QD solution. Note that the colloidal solution may contain, as a dispersant, publicly known ligands as a surface-modification agent for modifying the surfaces of the QDs.

As described above, the solvent is suitably a non-polar organic solvent with an SP value of from 6.5 to 9.4, both inclusive.

Note that the concentration of the colloidal QD solution is not limited in any particular manner so long as the colloidal QD solution has such a concentration or viscosity as to allow coating with the colloidal QD solution and, similarly to known examples, may be specified in a suitable manner depending on the coating method.

The colloidal QD solution is applied by, for example, spin-coating or inkjet coating. Note that the colloidal QD solution is dried (removed) by, for example, vaporizing the solvent through baking. Note that the drying temperature (baking temperature) is not limited in any particular manner, but is preferably set to a temperature at which the solvent can be sufficiently removed, to prevent thermal damage. Specifically, the drying temperature is preferably set to a temperature in a range of approximately 50 to 130° C.

Note that in step S25, the EML 54R is formed in the subpixels RSP, the EML 54G is formed in the subpixels GSP, and the EML 54B is formed in the subpixels BSP, each as one of the EMLs 54, in any order. The EML 54R, the EML 54G, and the EML 54B are formed using different materials by a known method that is not limited in any particular manner. As an example, the EML 54R, the EML 54G, and the EML 54B are formed using different materials by lift-off.

In such a case, for example, first of all, a template for lift-off is formed in an area other than an EML formation area (in a non-formation area where no EMLs 54 are to be formed) on the HTL 53, which serves as an underlying layer. Next, the entire underlying layer is coated with a colloidal QD solution (QD dispersed solution) containing QDs and a solvent, thereby forming a QD film coating across the entire underlying layer, and thereafter the template is lifted off. Hence, the EMLs 54 are formed in a desired pattern in the EML formation area.

Note that the template can be formed by, for example, applying and thereafter calcinating a resist for the template, exposing the resist to UV light (ultraviolet light) using a mask, and thereafter developing the resist.

As described above, when the display device 1 includes, as the subpixels SP, for example, the subpixels RSP, the subpixels GSP, and the subpixels BSP, the step of forming the template through the step of lifting off the template are repeated 3 times. Hence, the three-color EMLs 54 can be formed.

It should be noted however that this method is a mere example. The EML 54R, the EML 54G, and the EML 54B may be formed using different materials by other methods, for example, by etching.

In such a case, for example, first of all, the entire HTL 53, which serves as an underlying layer, is coated with a colloidal QD solution (QD dispersed solution) containing QDs and a solvent, thereby forming a QD film coating across the entire HTL 53. Next, a resist layer is stacked on the QD film, exposed to light, and developed, thereby forming a resist pattern in the EML formation area. Thereafter, those parts of the QD film that are not covered with the resist pattern is etched away with an etchant, and thereafter the resist pattern is lifted off. Hence, the EMLs 54 are formed in a desired pattern in the EML formation area.

In such a case, as described above, when the display device 1 includes, as the subpixels SP, for example, the subpixels RSP, the subpixels GSP, and the subpixels BSP, the step of forming the QD film through the step of lifting off the resist pattern are repeated 3 times. Hence, the three-color EMLs 54 can be formed.

The electron transport layer material colloidal solution used to form the ETL 56 in step S26 is, as described above, prepared in advance in step S31 before step S26.

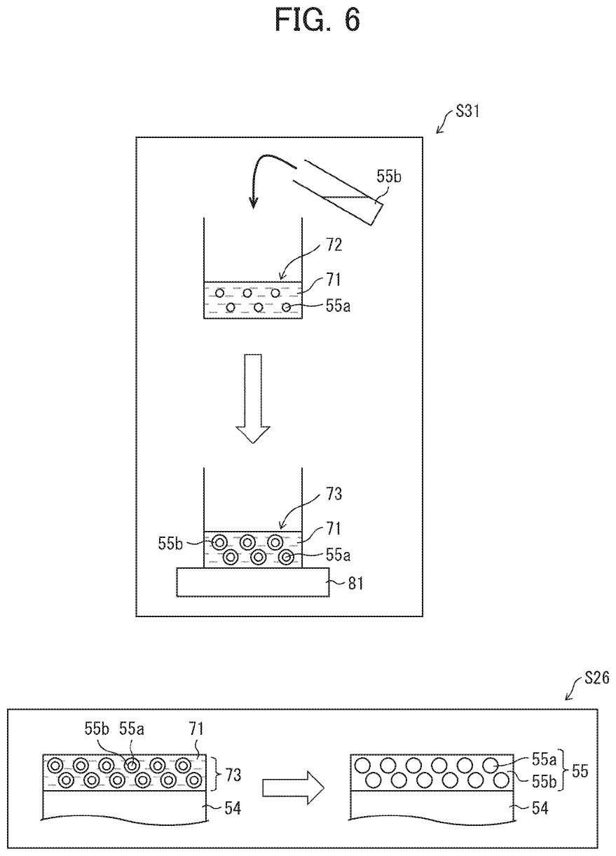

FIG. 6 is a schematic cross-sectional view of a part of the step of forming the light-emitting element layer 5 shown in FIG. 4. FIG. 6 shows the step of preparing an electron transport layer material colloidal solution denoted by S31 in FIG. 5 and the step of forming an electron transport layer denoted by S26 in FIG. 5. Note that in FIG. 6, for convenience of illustration, the oxide semiconductor nanoparticles 55a are shown enlarged, and not all the oxide semiconductor nanoparticles 55a are shown.

In step S31, as denoted by S31 FIGS. 5 and 6, a colloidal solution 73 containing the oxide semiconductor nanoparticles 55a, the oxygen adsorbent 55b, and a solvent 71 is prepared as an electron transport layer material colloidal solution.

To this end, for example, as denoted by S31 in FIG. 6, first of all, the oxide semiconductor nanoparticles 55a are dispersed in the solvent 71 to prepare an oxide-semiconductor-nanoparticle-dispersed solution 72 containing the oxide semiconductor nanoparticles 55a and the solvent 71. Thereafter, the oxygen adsorbent 55b is added to, and mixed with, this oxide-semiconductor-nanoparticle-dispersed solution 72 for dissolution. Hence, the colloidal solution 73 is prepared.

As denoted by S31 in FIG. 6, the oxygen adsorbent 55b also functions as a dispersant for dispersing the oxide semiconductor nanoparticles 55a by, for example, being coordinated to the oxide semiconductor nanoparticles 55a as a surface-modification agent for modifying the surfaces of the oxide semiconductor nanoparticles 55a. Therefore, in the present embodiment, the colloidal solution 73 can be obtained without having to separately adding a dispersant.

As described above, the solvent 71 is suitably a polar organic solvent with an SP value of from 6.4 to 9.5, both inclusive.

As described above, the ETL 55 contains the oxygen adsorbent 55b in an amount of preferably from 0.2 parts by weight to 1.2 parts by weight, both inclusive, more preferably from 0.2 parts by weight to 1 part by weight, both inclusive, and even more preferably from 0.2 parts by weight to 0.6 parts by weight, both inclusive, per 1 part by weight of the oxide semiconductor nanoparticles 55a.

The oxide semiconductor nanoparticles 55a and the oxygen adsorbent 55b are not lost by, for example, sublimation through, for example, heating in step S26. The oxide semiconductor nanoparticles 55a and the oxygen adsorbent 55b remain as they are in the ETL 55 even after the ETL 55 is formed.

Therefore, the colloidal solution 73 contains the oxygen adsorbent 55b in an amount of preferably from 0.2 parts by weight to 1.2 parts by weight, both inclusive, more preferably from 0.2 parts by weight to 1 part by weight, both inclusive, and even more preferably from 0.2 parts by weight to 0.6 parts by weight, both inclusive, per 1 part by weight of the oxide semiconductor nanoparticles 55a.

Note that the concentration of the colloidal solution 73 is not limited in any particular manner so long as the colloidal solution 73 has such a concentration or viscosity as to allow coating with the colloidal solution 73 and, similarly to known examples, may be specified in a suitable manner depending on the coating method.

In addition, it is preferable to use ultrasonic waves in mixing the oxide semiconductor nanoparticles 55a and the oxygen adsorbent 55b and in preparing the colloidal solution 73. The oxide semiconductor nanoparticles 55a and the oxygen adsorbent 55b can be uniformly mixed for uniform dispersion in the solvent 71, by adding the oxygen adsorbent 55b to the oxide-semiconductor-nanoparticle-dispersed solution 72 and thereafter applying the ultrasonic waves produced by an ultrasonic wave generator 81 for vibration under ultrasonic waves. Note that the ultrasonic waves may be applied for a duration that is not limited in any particular manner and may be applied, for example, approximately 10 minutes.

Step S26 is performed after step S25 and step S31 are performed. In step S26, the ETL 55 is formed by liquid-phase film formation. As denoted by S26 in FIGS. 5 and 6, in step S26, first of all, each EML 54 is coated with the colloidal solution 73 to form a coating film on the colloidal solution 73. Next, the ETL 55 containing the oxide semiconductor nanoparticles 55a and the oxygen adsorbent 55b is formed by removing the solvent 71 contained in the coating film to dry the coating film.

The colloidal solution 73 is applied by, for example, spin-coating or inkjet coating.

In addition, the colloidal solution 73 is dried (removed) by, for example, vaporizing the solvent through baking. The drying temperature (baking temperature) for the coating film is not limited in any particular manner so long as the drying temperature is higher than or equal to the evaporation temperature of the solvent 71 and lower than the boiling point of the oxygen adsorbent 55b. However, the drying temperature is preferably set to a temperature at which the solvent 71 can be sufficiently removed, to prevent thermal damage to the oxide semiconductor nanoparticles 55a, the oxygen adsorbent 55b, and the QDs 54a. Specifically, the drying temperature is preferably set to a temperature approximately in a range of 50 to 130° C.

When the ETL 55R, the ETL 55G, and the ETL 55B are made using different materials in step S26, the ETL 55R is formed in the subpixels RSP, the ETL 55G is formed in the subpixels GSP, and the ETL 55B is formed in the subpixels BSP, each as the ETL 55, in any order.

The ETL 55R, the ETL 55G, and the ETL 55B are formed using different materials by a known, publicly known method, for example, by the same method as the EML 54R, the EML 54G, and the EML 54B are formed using different materials.

Note that the same description is applicable when the HIL 52R, the HIL 52G, and the HIL 52B are formed using different materials, and when the HTL 53R, the HTL 53G, and the HTL 53B are formed using different materials.

The light-emitting elements ES and the display device 1 in accordance with the present embodiment can be manufactured by these steps.

### EXAMPLES

A description is given next of the effects of the light-emitting element ES in accordance with the present embodiment by way of examples and comparative examples. Note that the light-emitting element ES in accordance with the present embodiment is not limited only to the examples below.

### External Quantum Efficiency

Note that throughout the examples and comparative examples below, the external quantum efficiency (N_{φ(exe)}) was evaluated by means of the number of photons (Np) extracted from a unit area of a cell fabricated as a light-emitting element for the purpose of evaluation with respect to the number of carriers (Ne) injected to the cell, as represented by the following expressions.

$$\begin{matrix}N p = λ / hc \times P \times 1 / S ( 1 / {m}^{2} ) \\ Ne = I / e \times 1 / S ( 1 / {m}^{2} ) \\ {N}_{φ ( exe )} = N p / Ne \times 100 = ( P \times λ \times e ) / ( hc \times I ) \times 100 ( \% )\end{matrix}$$

where I is an electric current (A), P is light intensity (light amount measurement (W)), S is the area of the cell (element area (m²)), λ is a peak emission wavelength (m), e is the elementary charge (A·s), h is Planck's constant (J·s), and c is the speed of light (m·s⁻¹).

The electric current (I) was measured using a 2400-type Source Meter manufactured by Keithley Instrument Inc. The light intensity (P) was measured using a light intensity meter (model number: BM-5A) manufactured by Topcon House Corp. The area of the cell was set to 4×10⁻⁶ (m²). The peak emission wavelength (λ) was set to 536 (nm). Planck's constant was set to 6.626×10⁻³⁴ J·s. The elementary charge (e) was set to 1.602×10⁻¹⁹ A·s. The speed of light (c) was set to 2.998×10⁸ (m·s⁻¹).

### Example 1

First, an ITO substrate that carried ITO thereon as an anode was prepared and rinsed. Meanwhile, the PEDOT:PSS prepared by so doping PEDOT with PSS that the PVP doping amount per 1 part by weight of PEDOT was equal to 6 parts by weight was dissolved (dispersed) in water, to prepare a 1.5 wt % aqueous PEDOT:PSS-PVP solution.

Next, after the ITO substrate was coated with the aqueous PEDOT:PSS solution by spin-coating, the ITO substrate was baked at 150° C. for 30 minutes to evaporate the solvent. An HTL was hence formed with a thickness (design value) of 30 nm.

Next, after the HIL was coated with a solution prepared by dissolving (dispersing) TFB in chlorobenzene to 8 mg/mL by spin-coating, the ITO substrate was baked at 110° C. for 30 minutes to evaporate the solvent. An HTL was hence formed with a thickness (design value) of 30 nm.

Next, after the HTL was coated, by spin-coating, with a colloidal QD solution prepared by dispersing QDs with a Cd/Se core/shell structure in octane to 20 mg/mL, the ITO substrate was baked at 110° C. for 10 minutes to evaporate the solvent. An EML was hence formed with a thickness (design value) of 20 nm.

Meanwhile, a 5 wt % ZnO-NP dispersed solution was prepared containing ZnO nanoparticles with a median diameter (D50) of 16.66 nm (hereinafter, referred to as “ZnO-NP”) and ethanol. Then, BHT (dibutylhydroxytoluene) as an oxygen adsorbent was added to, and mixed with, this ZnO-NP dispersed solution in such a manner that the resultant mixture contains BHT in an amount of 1 part by weight for every 5 parts by weight of ZnO-NP. Hence, a colloidal ZnO-NP/BHT solution was prepared containing ZnO-NP, BHT, and ethanol.

Next, after the EML was coated with the colloidal ZnO-NP/BHT solution by spin-coating, the ITO substrate was baked at 110° C. for 30 minutes to evaporate the solvent. Hence, An ETL was formed with a thickness (design value) of 50 nm.

Next, Al was vapor-deposited onto the ETL to form a cathode with a thickness (design value) of 100 nm.

Thereafter, a stack body including all the layers from the HIL through the cathode formed on the ITO substrate was sealed with a glass cover. Note that all these series of procedures were done in the atmosphere. A cell that emitted red light was hence fabricated as a light-emitting element for the purpose of evaluation in the atmosphere. Next, the external quantum efficiency of the fabricated cell was determined.

### Examples 2 to 6

A cell was fabricated in the atmosphere as a light-emitting element for the purpose of evaluation by the same procedures as in Example 1, except that the blend ratio of BHT to ZnO-NP was changed as shown in Table 1 below. Thereafter, the external quantum efficiency of the fabricated cell was determined.

### Comparative Example 1

A cell was fabricated in the atmosphere as a light-emitting element for the purpose of evaluation by the same procedures as in Example 1, except that no oxygen adsorbent was added to the ZnO-NP. In other words, a cell was fabricated in the atmosphere as a light-emitting element for the purpose of evaluation by the same procedures as in Example 1, except that in the present comparative example, the ETL was formed by using a 5 wt % ZnO-NP dispersed solution instead of a colloidal ZnO-NP/BHT solution. Thereafter the external quantum efficiency of the fabricated cell was determine.

### Reference Example 1

A cell was fabricated in an inert atmosphere as a light-emitting element for the purpose of evaluation by the same procedures as in Comparative Example 1, except that the series of procedures were done in an inert atmosphere. Thereafter, the external quantum efficiency of the fabricated cell was determined.

Table 1 collectively shows the mix ratios (blend ratios) of ZnO-NP and an oxygen adsorbent and the external quantum efficiencies of the fabricated cells for Examples 1 to 6, Comparative Example 1, and Reference Example 1.

TABLE 1

| | | Oxygen | Blend Ratio of | External |
|---|---|---|---|---|
| | ZnO—NP | Adsorbent | Oxygen Adsorbent | Quantum |
| | (parts by | (parts by | to 1 Part by | Efficiency |
| | weight) | weight) | Weight of ZnO—NP | (%) |
| Example 1 | 5 | 1 | 0.2 | 9.2 |
| Example 2 | 5 | 2 | 0.4 | 9.8 |
| Example 3 | 5 | 3 | 0.6 | 9.0 |
| Example 4 | 5 | 4 | 0.8 | 8.7 |
| Example 5 | 5 | 5 | 1.0 | 8.4 |
| Example 6 | 5 | 6 | 1.2 | 7.6 |
| Comparative | 5 | — | — | 6.2 |
| Example 1 | | | | |
| Reference | 5 | — | — | 9.5 |
| Example 1 | | | | |

Table 1 demonstrates that the external quantum efficiency significantly decreases when the cell was fabricated in the atmosphere without using an oxygen adsorbent in forming an ETL as in Comparative Example 1 in comparison with Reference Example 1 where the same procedures were done in an inert atmosphere as in Comparative Example 1.

However, to industrially manufacture light-emitting elements and light-emitting devices including the light-emitting elements, investment in equipment for that purpose is needed to perform coating with a colloidal solution containing oxide semiconductor nanoparticles in an inert atmosphere as in Reference Example 1. Besides, the operating environment needs to be adjusted and maintained, which adds to the production cost of the light-emitting element and the light-emitting device.

On the other hand, the present embodiment does not require any procedures to be done in such an inert atmosphere. The present embodiment can restrain or prevent decreases in the external quantum efficiency even when the cell is fabricated in the atmosphere by using an oxygen adsorbent in forming the ETL as in Examples 1 to 6 in comparison with when no oxygen adsorbent is used in forming the ETL as in Comparative Example 1.

In addition, the results shown in Examples 1 to 6 demonstrate that the blend ratio of an oxygen adsorbent to 1 part by weight of oxide semiconductor nanoparticles is preferably from 0.2 parts by weight to 1.2 parts by weight, both inclusive, more preferably from 0.2 parts by weight to 1 part by weight, both inclusive, and more preferably from 0.2 parts by weight to 0.6 parts by weight, both inclusive. In particular, when the blend ratio of an oxygen adsorbent to 1 part by weight of oxide semiconductor nanoparticles is from 0.2 parts by weight to 0.6 parts by weight, both inclusive, the resultant external quantum efficiency is comparable to the external quantum efficiency available when the cell is fabricated in an inert atmosphere.

As described here, the present embodiment enables restraining or preventing decreases in the external quantum efficiency even when the light-emitting element is manufactured in the atmosphere, by using an oxygen adsorbent in forming the ETL so that the resultant ETL contains the oxygen adsorbent, which in turn enables the manufacture of the light-emitting element in the atmosphere.

Therefore, the present embodiment can provide a light-emitting element and a light-emitting device, both including an ETL containing oxide semiconductor nanoparticles, that are manufacturable in the atmosphere and capable of restraining or preventing decreases in the external quantum efficiency even when manufactured in the atmosphere and also provide a method of manufacturing such a light-emitting element.

### Variation Example 1

Note that FIGS. 1 to 3 show examples where the underlying electrode is the anode 51, the overlying electrode is the cathode 56, and the anode 51, the HIL 52, the HTL 53, the EML 54, the ETL 55, and the cathode 56 are provided in this order when viewed from the underlying side. It should be noted however that the present embodiment is not limited to these examples. Alternatively, the underlying electrode may be the cathode 56, and the overlying electrode may be the anode 51. In such a case, the order of stacking the functional layers is reversed from the case shown in FIGS. 1 to 3. In other words, in the light-emitting element ES, the cathode 56, the ETL 55, the EML 54, the HTL 53, the HIL 52, and the anode 51 may be provided in this order when viewed from the underlying side.

### Variation Example 2

In addition, there may be provided an electron injection layer (EIL) between the cathode 56 and the ETL 55. The EIL may be made of either an organic material or an inorganic material. When the EIL is made of an inorganic material, and the inorganic material is an oxide semiconductor, it is preferable that the EIL also contains an oxygen adsorbent.

### Variation Example 3

In addition, Embodiment 1 has described an example where the display device 1 includes the subpixels RSP, the subpixels GSP, and the subpixels BSP as subpixels. This combination is however not the only possibility.

### Variation Example 4

In addition, Embodiment 1 has described an example where the light-emitting device is a display device. The light-emitting element ES can be particularly suitably used as a light source in the display device 1. However, the light-emitting device in addition to the present disclosure is not limited to display devices. The light-emitting element ES may be used as a light source in light-emitting devices other than display devices.

The present disclosure is not limited to the description of the embodiments above and may be altered within the scope of the claims. Embodiments based on a proper combination of technical means disclosed in different embodiments are encompassed in the technical scope of the present disclosure Furthermore, new technological features can be created by combining different technical means disclosed in the embodiments.

1. A light-emitting element comprising:
an anode;
a cathode;
a quantum-dot light-emitting layer containing quantum dots between the anode and the cathode; and
an electron transport layer between the cathode and the quantum-dot light-emitting layer, wherein
the electron transport layer contains oxide semiconductor nanoparticles and an oxygen adsorbent.

2. The light-emitting element according to claim 1, wherein the oxygen adsorbent dissolves in a polar organic solvent.

3. The light-emitting element according to claim 2, wherein the polar organic solvent has an SP value of 10.0 or higher.

4. The light-emitting element according to claim 3, wherein the SP value of the polar organic solvent is from 10.0 to 14.8, both inclusive.

5. The light-emitting element according to claim 1, wherein the oxygen adsorbent is an aromatic oxygen adsorbent.

6. The light-emitting element according to claim 1, wherein the oxygen adsorbent is a phenolic oxygen adsorbent.

7. The light-emitting element according to claim 1, wherein the oxygen adsorbent is at least one species selected from the group consisting of dibutylhydroxytoluene, 2,6-di-tert-butyl-4-methoxyphenol, and 3-tert-butyl-4-hydroxyanisole.

8. The light-emitting element according to claim 1, wherein the oxygen adsorbent contains dibutylhydroxytoluene.

9. The light-emitting element according to claim 1, wherein the electron transport layer contains the oxygen adsorbent in an amount of from 0.2 parts by weight to 1.2 parts by weight, both inclusive, per 1 part by weight of the oxide semiconductor nanoparticles.

10. The light-emitting element according to claim 1, wherein the electron transport layer contains the oxygen adsorbent in an amount of from 0.2 parts by weight to 1 part by weight, both inclusive, per 1 part by weight of the oxide semiconductor nanoparticles.

11. The light-emitting element according to claim 1, wherein the electron transport layer contains the oxygen adsorbent in an amount of from 0.2 parts by weight to 0.6 parts by weight, both inclusive, per 1 part by weight of the oxide semiconductor nanoparticles.

12. The light-emitting element according to claim 1, wherein the oxide semiconductor nanoparticles have a median diameter (D50) in terms of volume in a range of from 1.5 nm to 8 nm, both inclusive.

13. The light-emitting element according to claim 1, wherein
the quantum-dot light-emitting layer contains red-light-emitting quantum dots as the quantum dots, and
the oxide semiconductor nanoparticles have a median diameter (D50) in terms of volume in a range of from 5 nm to 8 nm, both inclusive.

14. The light-emitting element according to claim 1, wherein
the quantum-dot light-emitting layer contains green-light-emitting quantum dots as the quantum dots, and
the oxide semiconductor nanoparticles have a median diameter (D50) in terms of volume in a range of from 3 nm to 5 nm, both inclusive.

15. The light-emitting element according to claim 1, wherein
the quantum-dot light-emitting layer contains blue-light-emitting quantum dots as the quantum dots, and
the oxide semiconductor nanoparticles have a median diameter (D50) in terms of volume in a range of from 1.5 nm to 3 nm, both inclusive.

16. The light-emitting element according to claim 1, wherein the oxide semiconductor contains zinc.

17. The light-emitting element according to claim 1, wherein the oxide semiconductor is zinc oxide.

18. A light-emitting device comprising the light-emitting element according to claim 1.

19. A method of manufacturing a light-emitting element including: an anode; a cathode; a quantum-dot light-emitting layer containing quantum dots between the anode and the cathode; and an electron transport layer between the cathode and the quantum-dot light-emitting layer, the method comprising:
a step of preparing a colloidal solution containing oxide semiconductor nanoparticles, an oxygen adsorbent, and a solvent; and
a step of forming the electron transport layer by forming a coating film of the colloidal solution in atmosphere and thereafter drying the coating film.

20. The method according to claim 19, wherein in the step of forming the electron transport layer, the coating film is dried at a temperature that is equal to or above an evaporation temperature of the solvent and that is below a boiling point of the oxygen adsorbent.

21. (canceled)

22. (canceled)
